(19) United States
(12) Patent Application Publication
(10) Pub. No.: US 2010/0252084 A1
(43) Pub. Date: Oct. 7, 2010

(54) THERMOELECTRIC MODULE

(76) Inventor: Akio Konishi, Kanagawa (JP)

Correspondence Address: KRATZ, QUINTOS & HANSON, LLP, 1420 K Street, N.W., 4th Floor, WASHINGTON, DC, 20005, US

(21) Appl. No.: 12/743,699

(22) PCT Filed: Nov. 14, 2008
(86) PCT No.: PCT/JP2008/070792

§ 371 Date: May 19, 2010

(30) Foreign Application Priority Data
Nov. 20, 2007 (JP) 2007-300484

(51) Int. Cl. H01L 35/00

(52) U.S. Cl. 136/200

(57) ABSTRACT

Thermoelectric elements are arranged with a high density in a peripheral region surrounding a center region or in an outer circumferential region of an opposing surface of a substrate instead of being arranged in the center region of the opposing surface. As compared to the case when the thermoelectric elements are arranged in the center of the opposing surface, when the thermoelectric elements are arranged in the region excluding the center region of the opposing surface, the thermoelectric element serving as a reference point of warp is positioned at an outer circumference side, i.e., the distance between the warp reference point and the outer circumference of the substrate becomes shorter. As the distance between the warp reference point and the outer circumference of the substrate becomes shorter, the displacement amount and the force of the warp caused at the outer circumference of the substrate become smaller. Moreover, when the thermoelectric elements are arranged with a high density, the force of each of the thermoelectric elements pulled by the substrate warp becomes smaller. Thus, by reducing the displacement amount and the force of the warp generated at the outer circumference of the substrate, it is possible to prevent a damage of the thermoelectric elements caused by the substrate warp.

### TECHNICAL FIELD

The present invention relates to a thermoelectric module in which heat is transferred from one substrate to the other substrate by utilizing the Peltier effect that is generated with energization to a series circuit constituted by thermoelectric elements and electrodes, and more particularly, to prevention of the thermoelectric elements from being damaged due to warp of the substrates caused by pre-tinned solder.

### BACKGROUND ART

A thermoelectric module is used as a temperature regulator for various instruments and equipment. FIG. 18 illustrates a configuration of a common thermoelectric module. A thermoelectric module 9 comprises two mutually-opposing substrates 11 and 21, plural electrodes 12 and 22 formed on opposing surfaces 11a and 12a of each of the substrates 11 and 21, plural p-type thermoelectric elements 31 and n-type thermoelectric elements 32 (hereinafter simply called “thermoelectric elements 31 and 32”) that are formed on the opposing surfaces 11a and 21a of each of the substrates 11 and 21 in such a manner that one end thereof is joined to the opposing surface 11a of the substrate 11 via an electrode 12, and the other end thereof is joined to the opposing surface 21a of the other substrate 21 via an electrode 22, metalized layers 13 and 23 formed on reverse surfaces 11b and 21b of each of the substrates 11 and 21, and pre-tinned solder layers 14 and 24 formed on the reverse surfaces 11b and 21b of each of the substrates 11 and 21 via the metalized layers 13 and 23. These plural electrodes 12 and 22 and plural thermoelectric elements 31 and 32 are sequentially connected in such a cycle as electrode 12, thermoelectric element 31, electrode 22, thermoelectric element 32, electrode 12 and so forth to constitute a series circuit. On an opposing surface of one substrate, that is, the opposing surface 11a of the substrate 11 in this case, are formed end electrodes 41 serving as the ends of the series circuit, to which a lead wire or pillar-shaped conductor not shown in drawings is connected.

When an electric current is supplied to the series circuit via the lead wire or pillar-shaped conductor, heat conduction in one direction is generated between the substrate 11 and the substrate 21 by the Peltier effect. At that time, heat absorbing action is generated at one substrate and heat dissipating action is generated at the other substrate. When the direction of the electric current supply is reversed, heat conduction in the reverse direction is generated so that the heat absorbing action and the heat dissipating action are reversed. Here, it is supposed that the substrate 11 is heat absorption side and the substrate 21 is heat dissipation side.

The electrodes 12 and 22 are made of metal, such as copper plating, and the thermoelectric elements 31 and 32 are made of Bi—Te group alloy. The electrodes 12 and 22 and the thermoelectric elements 31 and 32 are joined to each other with AuSn solder.

The substrates 11 and 12 are made of insulating ceramic, mainly such as Al₂O₃ (alumina) or AlN (aluminum nitride). The coefficient of thermal expansion of Al₂O₃ is 6.7×10⁻⁶/° C. and the coefficient of thermal expansion of AlN is 4.5×10⁻⁶/° C. On the other hand, the pre-tinned solder layers 14 and 24 are made of Sn—Ag—Cu group solder. The coefficient of thermal expansion of Sn—Ag—Cu group solder is 21.5×10⁻⁶/° C. As seen above, there is triple or greater difference in the coefficient of thermal expansion between Al₂O₃ and AlN. Due to the difference, if the temperature of both the substrates 11 and 21 and the pre-tinned solder layers 14 and 24 is lowered after the metalized layers 13 and 23 are coated with the pre-tinned solder layers 14 and 24, the pre-tinned solder layers 14 and 24 are more contracted than the substrates 11 and 21 so that the reverse surfaces 11b and 21b are caused to be pulled, resulting in that the substrates 11 and 21 receive a force that causes the substrates 11 and 21 to be warped toward the side of the reverse surfaces 11b and 21b. As a result, thermoelectric elements 31 and 32 are pulled by this force and might be damaged. If that occurs, unfavorable effect would be brought to the thermoelectric modules themselves. Theoretically, the warp of the substrates 11 and 21 due to the difference in coefficient of thermal expansion would be reduced if the material of the substrates 11 and 21 and the material of the pre-tinned solder layers 14 and 24 are chosen so that the coefficients of thermal expansion of these materials are close to each other, and as a result, damage of thermoelectric elements 31 and 32 would be eliminated. However, under the present circumstances, it is difficult to use materials other than the aforementioned materials as a material of the substrates 11 and 21 and a material of the pre-tinned solder layers 14 and 24.

As a technique for preventing damages of thermoelectric modules due to the warp of substrates, there is, for example, invention disclosed in Patent document 1. According to the invention of Patent document 1, considering that force of warp generating at four corners of a quadrilateral substrate is the greatest, damage of thermoelectric elements is prevented by not disposing thermoelectric elements on the four corners of the opposing surface of the substrate. Therefore, Patent document 1 discloses a scheme for arrangement of thermoelectric elements on a substrate.

Incidentally, Patent document 2 also discloses an arrangement of thermoelectric elements on a substrate although it does not relate to the technique of preventing damage of thermoelectric elements due to the warp of substrates on which pre-tinned solder layer is formed. According to the invention of Patent document 2, thermoelectric elements are arranged on opposing surfaces of substrates, sparsely in the center region and densely in the outer circumference region, thereby to equalize temperature distribution on the substrate.

Further, as a technique for preventing damages of thermoelectric modules due to the warp of substrates, other than the invention of Patent document 1, there is invention disclosed in Patent document 3. Of thermoelectric modules, there is a thermoelectric module whose two opposing substrates differ in size from each other. In such a thermoelectric module having two opposing substrates that differ in size, input and output terminals are formed in a region extending from an opposing surface of a larger substrate. These input and output terminals are connected to a circuit constituted by electrodes and thermoelectric elements. In the invention of Patent document 3, thermoelectric elements are prevented from being damaged by making the metalized layer formed on the reverse surface of the larger substrate the same shape as the metalized layer of the smaller substrate. If the metalized layer on which a pre-tinned solder is coated is small, region of the pre-tinned solder becomes small and the warp of the substrates also becomes small.

Further, as a technique for preventing damages of thermoelectric modules due to the warp of substrates, there is invention disclosed in Patent document 4, other than the invention disclosed in Patent document 1. In the invention of Patent document 4, damage of thermoelectric elements is prevented by forming a metalized layer in a divided manner on the reverse surface of a substrate. If a metalized layer on which pre-tinned solder is coated is divided, the pre-tinned solder is also divided, and therefore a force that causes warp acting to the substrate is divided.

Patent document 1: Japanese patent application publication 2004-172216

Patent document 2: Japanese patent application publication H11-307826

Patent document 3: Japanese patent application publication 2007-67231

Patent document 4: Japanese patent application publication 2005-79210

### DISCLOSURE OF THE INVENTION

### Problems to be Solved by the Invention

In the invention of Patent document 1, thermoelectric elements are not disposed on four corners of the opposing surface of a substrate. In such an arrangement, the number of thermoelectric elements disposed on the outer circumferential portion of the opposing surface is caused to be small, and as a result, rigidity of the thermoelectric module as a whole becomes lower. Further, although the invention of Patent document 3 can be applied to a thermoelectric module having two substrates of different sizes, it cannot be applied to a thermoelectric module having two substrates of the same size. Further, if a metalized layer is divided as in the invention of Patent document 4, uneven distribution in each pre-tinned solder would likely to occur when the pre-tinned solder is coated. As a result, a portion of the substrate on which thicker pre-tinned solder is formed can be warped greater, and thus thermoelectric elements might be damaged. As stated above, according to the inventions of Patent documents 1, 3 and 4, new problems would emerge corresponding to the characteristics of the inventions. Therefore, technique capable of preventing damage of thermoelectric elements due to the warp of a substrate, which uses a method different from those in the inventions of Patent documents 1, 3 and 4, is being waited.

Further, as shown in FIG. 19, in the inventions of Patent document 1 and 3, the substrates 11 and 21 are warped at thermoelectric elements 31c and 32c that are disposed at a center c of the opposing surfaces 11a and 21a serving as a warp reference point. Since the displacement amount and the force of the warp become larger as the distance from the center c becomes larger, the possibility of damage for thermoelectric elements 31 and 32 arranged on the outer circumference of the substrates 11 and 21 becomes higher. In other words, the problem for thermoelectric elements to be damaged cannot totally be solved.

The present invention has been made in view of the foregoing circumstances, and an object of the present invention is to prevent a damage of the thermoelectric modules caused by the substrate warp by reducing the displacement amount and the force of the warp generated at the outer circumference of the substrate.

### Means to Solve the Problems

To solve the above problems, the first invention provides a thermoelectric module comprising two mutually-opposing substrates; a plurality of electrodes formed on an opposing surface of each of the substrates; and a plurality of thermoelectric elements arranged on the opposing surface of each of the substrates in such a manner that one end thereof is joined to the opposing surface of one of the substrates via an electrode, and the other end thereof is joined to the opposing surface of the other one of the substrates via an electrode, in which the plurality of electrodes and the plurality of thermoelectric elements constitute a series circuit, and heat is transferred from the one of the substrates to the other substrate by passing an electric current through the series circuit, wherein the plurality of thermoelectric elements are arranged with a high density in a region excluding a center region of the opposing surface of each of the substrates.

In the first invention, thermoelectric elements are arranged with a high density in a peripheral region surrounding a center region or in an outer circumferential region of an opposing surface of a substrate instead of being arranged in the center of the opposing surface, when the thermoelectric elements are arranged in the region excluding the center region of the opposing surface, the thermoelectric element serving as a reference point is positioned at an outer circumference side, i.e., the distance between the warp reference point and the outer circumference of the substrate becomes shorter, the displacement amount and the force of the warp caused at the outer circumference of the substrate become smaller. Moreover, when the thermoelectric elements are arranged with a high density, the force for each of the thermoelectric elements pulled by the substrate warp becomes smaller. In addition, lowering of rigidity of thermoelectric module itself can be prevented.

The second invention is characterized in that, in the first invention, the center region has an area which is equal to or larger than four times of an area to which one of the thermoelectric elements is arranged, with respect to the opposing surface of each of the substrates.

The second invention defines a condition in which the center region of the opposing surface has an area which is equal to or larger than four times of a setting area of one thermoelectric element.

The third invention is characterized in that, in the first invention, a reinforcing member is formed in the center region.

In the third invention, a reinforcing member is formed in the center region of the opposing surface of the substrate. Since the reinforcing member acts against the warp of the substrates, it becomes difficult to generate a warp to the substrate. As the reinforcing member, a hard member that does not affect the performance of the thermoelectric module is suited.

The fourth invention is characterized in that, in the first invention, an electrode to be connected to any of the plurality of thermoelectric elements extends into the center region.

In the fourth invention, an electrode, which is formed in the peripheral region of the opposing surface of the substrate, extends into the center region. Since the electrode acts against the warp of the substrate, it becomes difficult to generate a warp to the substrate. Further, if the electrode does not extend into the center region, unevenness might occur in the heat distribution of the thermoelectric module. However, in the case where the electrode extends into the center region, heat is transferred to the substrate also from the center region, and therefore, unevenness will not occur in the heat distribution of the thermoelectric module.

The fifth invention is characterized in that, in the first invention, the plurality of thermoelectric elements are arranged so that a change amount in a resistance value of the series circuit before and after formation of a pre-tinned solder layer on a reverse surface side of each of the substrates is 1.0% or smaller as compared with a resistance value of the series circuit before the formation of the pre-tinned solder layer.

A resistance value of the series circuit formed by electrodes and thermoelectric elements changes before and after the formation of a pre-tinned solder layer on a reverse surface side of each of the substrates. The rate of this change amount with respect to the resistance value of the series circuit before the formation of the pre-tinned solder layer is called resistance change rate. In the fifth invention, the plural thermoelectric elements are arrange so that the resistance change rate is 1.0% or smaller. If a thermoelectric element damages, the damaged portion serves as a resistor so that a resistance value of the circuit increases. In other words, if the damage is prevented, there is no increase in the resistance value of the circuit. The resistance change rate up to about 1.0% before and after the pre-tinning would be acceptable. Since displacement amount and the force of the warp generated at the outer circumference of the substrate changes in response to the arrangement of thermoelectric elements, the fifth invention sets a condition in which thermoelectric elements should be arranged in the region excluding the center region of the opposing surface so that the resistance change rate is up to 1.0% or smaller before and after the pre-tinning.

To solve the above problems, the sixth invention is a thermoelectric module having two mutually-opposing substrates; a plurality of electrodes formed on an opposing surface of each of the substrates; a plurality of thermoelectric elements arranged on the opposing surface of each of the substrates in such a manner that one end thereof is joined to the opposing surface of one of the substrates via an electrode, and the other end thereof is joined to the opposing surface of the other one of the substrate via an electrode; and a pre-tinned solder layer formed on a reverse surface of each of the substrates, in which the plurality of electrodes and the plurality of thermoelectric elements constitute a series circuit, and heat is transferred from the one of the substrates to the other substrate by passing an electric current through the series circuit, wherein a metalized layer is formed between the reverse surface of each of the substrates and the pre-tinned solder layer, and the electrodes are thicker than the metalized layer to an extent that a change amount in a resistance value of the series circuit before and after the formation of the pre-tinned solder layer on the reverse surface side of each of the substrates is 1.0% or smaller as compared with a resistance value of the series circuit before the formation of the pre-tinned solder layer.

In the sixth invention, the electrodes formed on the opposing surfaces of the substrates are made thicker than the metalized layers formed on the opposing surfaces of the substrates to the extent that resistance change amount is 1.0% or smaller. Since the electrode acts against the warp, the displacement amount of the force of the warp caused at the outer circumference of the substrate become smaller as the electrode becomes thicker. The sixth invention defines the electrodes under a condition as being thicker than the metalized layers.

### EFFECT OF THE INVENTION

According to the first invention, since thermoelectric elements are arranged in the region excluding the center region of the opposing surface of the substrates, the distance between the warp reference point and the outer circumference of the substrate becomes shorter, and as a result, the displacement amount and the force of the warp caused at the outer circumference of the substrate become smaller. Further, since the thermoelectric elements are arranged with a high density, the force for each of the thermoelectric elements to be pulled by the substrate warp becomes smaller. With such actions, the damage of thermoelectric elements caused by the warp of the substrate can be prevented.

Further, according to the first invention, by arranging thermoelectric elements with a high density in the peripheral region of a thermoelectric module, geometric moment of inertia of thermoelectric elements becomes greater so that a strong structure is obtained against a mechanical external force. Thus, damages of thermoelectric elements caused by an external force that is applied when the thermoelectric module is joined to a package, etc. can be reduced.

According to the sixth invention, the thickness of the electrodes reduces the displacement amount and the force of the warp caused at the outer circumference of the substrate. With such an action, it becomes possible to prevent the thermoelectric elements from being damaged by the warp of the substrate.

### BEST MODE FOR CARRYING OUT THE INVENTION

Exemplary embodiments of the present invention will be described below with reference to the accompanying drawings.

### First Exemplary Embodiment

FIG. 1 illustrates a basic configuration of a thermoelectric module according to a first exemplary embodiment.

A thermoelectric module 1 shown in FIG. 1 is the same as the conventional thermoelectric module 9 shown in FIG. 18 in their constituting components and the relation of connections among these components. What is different is the arrangement of the thermoelectric elements 31 and 32, and electrodes 12 and 22 with respect to the opposing surfaces 11a and 21a of the substrates 11 and 21. Thus, among each of the constituting components of the thermoelectric module 1 shown in FIG. 1, those which are the same as the constituting components of thermoelectric module 9 shown in FIG. 18 are denoted with the same symbols, and explanations relating to the constituting components and the relation of connections are omitted.

Each of the thermoelectric elements 31 and 32 is arranged in regions 11d and 21d excluding center regions 11c and 21c on the opposing surfaces 11a and 21a of the substrates 11 and 21. In the thermoelectric module 1, the number of each of the thermoelectric elements 31 and 32 is made equal to that in the conventional thermoelectric module 9 of the same size. Since each of the thermoelectric element 31 and 32 is evenly arranged in the entire regions of the opposing surfaces 11a and 21a in the thermoelectric module 9, a space between the thermoelectric elements 31 and 32 in the thermoelectric module 1 according to this exemplary embodiment is narrower than a space between the thermoelectric elements 31 and 32 in the thermoelectric module 9. In other words, the thermoelectric elements 31 and 32 are arranged in the regions 11d and 21d with a high density. The substrates 11 and 21 are of a quadrangular shape, and the thermoelectric elements 31 and 32 are arranged also in edges and four corners of the opposing surfaces 11a and 21a.

Reinforcing members 15 and 25 may be arranged in the center regions 11c and 21c of the opposing surfaces 11a and 21a. The reinforcing members 15 and 25 may be dummy electrodes made of the same material or of a different material. Since the reinforcing members 15 and 25 act against warping of the substrates 11 and 21, presence of the reinforcing members 15 and 25 in the center regions 11c and 21c generates an effect that it becomes difficult to generate a warp to the substrates 11 and 21. As the reinforcing member, a rigid member that does not affect the performance of the thermoelectric module is suited.

Further, as a replacement of the reinforcing members 15 and 25, portions of the electrodes 12 and 22 which are formed in a peripheral region thereof may extend into the center regions 11c and 22c. Since the electrodes 12 and 22 act against warping of the substrate, the extension of the electrodes 12 and 22 into the central regions 11c and 22c makes it difficult to generate a warp to the substrates 11 and 21. Further, in the case where the electrodes 12 and 22 do not extend into the center regions 11c and 21c, some unevenness might occur in heat distribution of the thermoelectric module 1. However, in the case where the electrodes 12 and 22 extend into the center regions 11c and 21c, heat is transferred to the center regions 11c and 21c as well as other regions 11d and 21d, and therefore, unevenness will not occur in the heat distribution of the thermoelectric module 1. For this reason, the effect is generated that makes it possible to attain farther equalization of the heat distribution.

As shown in FIG. 2, in the first exemplary embodiment, the substrates 11 and 21 are warped at the thermoelectric elements 31 and 32 arranged in inner circumferences of the regions 11d and 21d of the opposing surfaces 11a and 21a serving as reference points.

Comparing the case as shown in FIG. 19 in which the thermoelectric elements 31 and 32 are arranged at the center c of the opposing surfaces 11a and 21a with the case as shown in FIG. 2 in which the thermoelectric elements 31 and 32 are arranged at the regions 11d and 21d excluding the center regions 11c and 21c of the opposing surfaces 11a and 21a, the thermoelectric elements 31 and 32 that serve as reference points of warp are positioned at an outer circumference side, i.e., the distance between the reference point of warp and the outer circumference of the substrates 11 and 21 is shorter, in the latter than in the former. As the distance between the warp reference point and the outer circumference of the substrates 11 and 21 becomes shorter, the displacement amount X and the force F of the warp generated at the outer circumference of the substrates 11 and 21 become smaller. Moreover, by arranging the thermoelectric elements 31 and 32 with a high density, the force with which each one of the thermoelectric elements 31 and 32 is to be pulled due to the warp of the substrates 11 and 21 becomes smaller.

Next, by comparing some examples of configuration according to this exemplary embodiment with examples of other configurations, beneficial effectiveness of this exemplary embodiment is discussed. The beneficial effectiveness can be judged by degree of damage in the thermoelectric elements 31 and 32 after the pre-tinning, and the degree of damage in the thermoelectric elements 31 and 32 after the pre-tinning can be known by measuring a resistance change rate. Here, the resistance change rate is defined as follow. The resistance value of a series circuit formed by the electrodes 31 and 32 and the thermoelectric elements 31 and 32 changes before and after the formation of pre-tinned solder layers 14 and 24. The rate of the change amount of the resistance value before and after the pre-tinning with respect to the resistance value of the series circuit before the formation of the pre-tinned solder layers 14 and 24 is called a resistance change rate.

Hereafter, specific comparisons 1-3 are discussed by referring to FIGS. 3-8. In each of the comparisons, conditions of the substrates 11 and 21 and the thermoelectric elements 31 and 32, that is, while the material and size of the substrates 11 and 21, and the size and the number of pairs, etc. of the thermoelectric elements 31 and 32 are made the same, only the arrangement of the thermoelectric elements 31 and 32 is changed. And, a pre-tinned solder layer (Sn96.5Ag3.0Cu0.5: melting point 217° C., 30 μm or equivalent) is formed on the reverse surfaces 11b and 21b of the substrates 11 and 21. Inventors of the present invention set the value of the resistance change rate 1.0% as acceptability criterion value in each of the comparisons. Within this value or lower, it is determined that the degree of damage for the thermoelectric elements 31 and 32 is judged to be smaller.

[Comparison 1]

FIG. 3A illustrates an arrangement of the embodiment 1 in the comparison 1, and FIGS. 3B-3D illustrate arrangements of comparative examples 1-3 in the comparison 1. Each of the drawings in FIG. 3 shows the positions of thermoelectric elements 31 and 32 and the electrodes 22 with respect to the substrate 21 of heat dissipation side viewed from the substrate 11 of heat absorption side. As shown in FIG. 3A, the width of the substrate is denoted by W, and the length of the substrate is denoted by L. Also, although not being shown in the drawings, in the substrate 11, the surface opposing to the opposing surface 21a of the substrate 21 is termed an opposing surface 11a, and the region opposing to the center region 21c of the substrate 21 is termed a center region 11c. The same as the above is applied to FIGS. 5, 7, 9, 10, 12, 14 and 16.

FIG. 4 illustrates conditions of each of the examples in the comparison 1. As shown here, in the comparison 1, comparison was made with respect to four thermoelectric elements each having a substrate of W4.76 mm×L3.72 mm on which twenty pairs of thermoelectric elements having 0.32 mm square and 0.38 mm length are arranged. Incidentally, “pair number” here is referred to as total number of pairs in which a p-type thermoelectric element 31 and an n-type thermoelectric element 32 joined to one electrode 12 is counted as one pair.

As shown in FIG. 3A, in the embodiment 1, the thermoelectric elements 31 and 32 are arranged in the regions 11d and 21d excluding the center regions 11c and 21c on the opposing surfaces 11a and 21a of the substrates 11 and 21. In FIG. 4, this arrangement is called “center exclusion.” Further, in the embodiment 1, dummy electrodes are arranged in the center regions 11c and 21c. As shown in FIG. 3B, in the comparative example 1, the thermoelectric elements 31 and 32 are arranged with an equal interval in the entire regions of the opposing surfaces 11a and 21a. In FIG. 4, this arrangement is called “equal interval”. As shown in FIG. 3C, in the comparative example 2, the thermoelectric elements 31 and 32 are arranged in the regions 11d and 21d excluding the outer circumferential regions on the opposing surfaces 11a and 21a. In FIG. 4, this arrangement is called “outer exclusion”. As shown in FIG. 3D, in the comparative example 3, the thermoelectric elements 31 and 32 are densely arranged in the four corners on the opposing surfaces 11a and 21a, and sparsely arranged in other regions. In FIG. 4, this arrangement is called “dense corner/sparse center”.

As understood from the comparison of the resistance change rate in the embodiment 1 and the comparative examples 1-3 shown in FIG. 4, the resistance change rate of the embodiment 1 falls within the acceptability criterion value of 1.0% or smaller with respect to any of average value, maximum value and minimum value, and from this, it can be judged that the damage degree of thermoelectric elements 31 and 32 is small. On the other hand, the resistance change rates of the comparative examples 1-3 exceed the acceptability criterion value of 1.0% with respect to average value and maximum value, and from this, it can be judged that the damage degree of thermoelectric elements 31 and 32 is large.

Incidentally, the comparative example 3 coincides with the embodiment 1 on the point that thermoelectric elements 31 and 32 are not arranged in the center region of the opposing surfaces 11a and 21a. Reason why the comparative example 3 does not satisfy the acceptability criterion is considered to be that the center region where no thermoelectric elements 31 and 32 are arranged is too small. From this, it can be inferred that it is necessary for the center region to have a wide area to some extent.

[Comparison 2]

FIG. 5A illustrates an arrangement of embodiments 2 and 3 in the comparison 2, and FIG. 5B illustrates an arrangement of comparative examples 4 and 5 in the comparison 2. FIG. 6 illustrates conditions of each of the examples in the comparison 2. As shown here, in the comparison 2, comparison was made with respect to four thermoelectric elements each having a substrate of W4.42 mm×L5.66 mm on which twenty nine pairs of thermoelectric elements having 0.45 mm square and 0.38 mm length are arranged.

As shown in FIG. 5A, in the embodiments 2 and 3, the thermoelectric elements 31 and 32 are arranged in the regions 11d and 21d excluding the center regions 11c and 21c on the opposing surfaces 11a and 21a of the substrates 11 and 21. In FIG. 6, this arrangement is called “center exclusion.” Further, in the embodiments 2 and 3, dummy electrodes are arranged in the center regions 11c and 21c. As shown in FIG. 5B, in the comparative examples 4 and 5, the thermoelectric element 31 and 32 are arranged with an equal interval in the entire regions of the opposing surfaces 11a and 21a excluding four corners. In FIG. 6, this arrangement is called “corner exclusion”.

As understood from the comparison of the resistance change rate in the embodiments 2 and 3 and the comparative examples 4 and 5 shown in FIG. 6, the resistance change rate of the embodiments 2 and 3 falls within the acceptability criterion value of 1.0% or smaller with respect to any of average value, maximum value and minimum value, and from this, it can be judged that the damage degree of thermoelectric elements 31 and 32 is small. On the other hand, the resistance change rates of the comparative examples 1-3 exceed the acceptability criterion value of 1.0% with respect to average value and maximum value, and from this, it can be judged that the damage degree of thermoelectric elements 31 and 32 is large.

Incidentally, in the embodiments 2 and 3, the center regions 11c and 21c of the opposing surfaces 11a and 21a have an area which is as large as about five setting areas for one thermoelectric element.

[Comparison 3]

FIGS. 7A and 7B illustrate arrangements of the embodiments 4 and 5 in the comparison 3, and FIGS. 7C and 7D illustrate arrangements of the comparative examples 6 and 7 in the comparison 3. FIG. 8 illustrates conditions of each of the examples in the comparison 3. As shown here, in the comparison 3, comparison was made with respect to four thermoelectric elements each having a substrate of W3.1 mm×L2.5 mm on which ten pairs of thermoelectric elements having 0.27 mm square and 0.38 mm length are arranged.

As shown in FIGS. 7A and 7B, in the embodiments 4 and 5, the thermoelectric elements 31 and 32 are arranged in the regions 11d and 21d excluding the center regions 11c and 21c on the opposing surfaces 11a and 21a. In FIG. 8, this arrangement is called “center exclusion”. Further, in the embodiments 4 and 5, dummy electrodes are arranged in the center regions 11c and 21c. As shown in FIG. 7C, in the comparative example 6, the thermoelectric element 31 and 32 are arranged with an equal interval in the entire regions of the opposing surfaces 11a and 21a. In FIG. 8, this arrangement is called “equal interval.” As shown in FIG. 7D, in the comparative example 7, the thermoelectric element 31 and 32 are arranged with an equal interval in the entire regions of the opposing surfaces 11a and 21a excluding four corners. In FIG. 8, this arrangement is called “corner exclusion.”

As understood from the comparison of the resistance change rate in the embodiments 4 and 5 and the comparative examples 6 and 7 shown in FIG. 8, the resistance change rate of the embodiments 4 and 5 falls within the acceptability criterion value of 1.0% or smaller with respect to any of average value, maximum value and minimum value, and from this, it can be judged that the damage degree of thermoelectric elements 31 and 32 is small. On the other hand, the resistance change rates of the comparative examples 1-3 exceed the acceptability criterion value of 1.0% with respect to any of the average value, maximum value and minimum value, and from this, it can be judged that the damage degree of thermoelectric elements 31 and 32 is large. Further, although the resistance change rate of the comparative example 7 falls within the acceptability criterion value of 1.0% or smaller with respect to average value and minimum value, it exceeds the acceptability criterion value of 1.0% with respect to maximum value. From this, it can be judged that the damage degree of thermoelectric elements 31 and 32 is large, even though it is better than in the comparative example 6.

Incidentally, in the embodiment 4, the center regions 11c and 21c of the opposing surfaces 11a and 21a have an area which is equal to or larger than four times of the setting area for one thermoelectric element. From this, it can be inferred that it would be possible to suppress damages of the thermoelectric elements 31 and 32 due to pre-tinned solder if the center regions 11c and 21c have an area which is equal to or larger than four times of the setting area for thermoelectric elements 31 and 32.

FIGS. 9 and 10 illustrate another configuration of the embodiment 1 shown in FIG. 3. In embodiment 6 shown in FIG. 9, integrated dummy electrodes are arranged in the center regions 11c and 21c. In embodiment 7 shown in FIG. 10, electrodes 12 and 22 arranged in peripheral regions of the center regions 11c and 21c extend into the center regions. Since the arrangements of the thermoelectric elements 31 and 32 in the embodiments 6 and 7 are the same as the arrangement of the thermoelectric elements 31 and 32 in the embodiment 1, it is inferred that the resistance change rate is about the same level or lower.

According to the first exemplary embodiment, since the thermoelectric elements are arranged in the regions excluding the center region, distance between the reference point of warp and the outer circumference is shorter, and as a result, the displacement amount and force of the warp caused at the outer circumference of the substrates become smaller. Also, since the thermoelectric elements are arranged with a high density, the force with which each of the thermoelectric elements is pulled by the warp of the substrate becomes smaller. With such an action, it becomes possible to prevent damages of thermoelectric elements caused by the warp of substrates.

Further, in the first exemplary embodiment, by arranging the thermoelectric elements with a high density in the peripheral region of a thermoelectric module, geometric moment of inertia of thermoelectric elements becomes greater so that they have a strong structure against a mechanical external force. Thus, damages of thermoelectric elements caused by an external force applied when the thermoelectric module is joined to a package, etc. can be reduced.

### Second Exemplary Embodiment

FIG. 11 illustrates a basic configuration of a thermoelectric module according to a second exemplary embodiment.

A thermoelectric module 2 shown in FIG. 11 is the same as the conventional thermoelectric module 9 shown in FIG. 18 in many of their constituting components and the relation of connections among these components. What is different is differences in thickness of electrodes and metalized layers. Thus, among each of the constituting components of the thermoelectric module 2 shown in FIG. 11, those which are the same as the constituting components of thermoelectric module 9 shown in FIG. 18 are denoted with the same symbols and explanations relating to the constituting components and the relation of connections are omitted.

In the thermoelectric module 2 shown in FIG. 11, each of electrodes 12 and 22 are formed to have thickness greater than that of metalized layers 13 and 23. The difference between the thicknesses is to the extent that the resistance change rate is 1.0% or smaller.

Next, by comparing some examples of configuration according to this exemplary embodiment with examples of other configurations, beneficial effectiveness of this exemplary embodiment is discussed. As in the first exemplary embodiment, the beneficial effectiveness is judged by measuring the resistance change rate.

Hereafter, specific comparisons 4-6 are discussed by referring to FIGS. 12-17. In each of the comparisons, conditions of the substrates 11 and 21 and the thermoelectric elements 31 and 32, that is, the material and size of the substrates 11 and 21, and the size and the number of pairs, etc. of the thermoelectric elements 31 and 32 are made the same, and only the thickness of the electrodes 12 and 22 and the metalized layers 13 and 23 is changed. In this regard, however, in each example, sum of the thickness of the electrodes 12 and 22 and the thickness of the metalized layers 13 and 23 are unified to be 40 μm, and each of the respective thicknesses is changed within the sum. Further, the electrodes 12 and 22 and the metalized layers 13 and 23 are formed by copper plating. And, a pre-tinned solder layer (Sn96.5Ag3.0Cu0.5: melting point 217° C., 30 μm or equivalent) is formed on the reverse surfaces 11b and 21b of the substrates 11 and 21. Inventors of the present invention set the value of the resistance change rate 1.0% as acceptability criterion value in each of the comparisons. Within this value or lower, it is determined that the degree of damage for the thermoelectric elements 31 and 32 is judged to be smaller.

[Comparison 4]

FIG. 12 illustrates an arrangement in the comparison 4. FIG. 12 shows the position of thermoelectric elements 31 and 32 and the electrode 22 with respect to the substrate 21 of heat dissipation side viewed from the substrate 11 of heat absorption side. FIG. 13 illustrates conditions of each of the examples in the comparison 4. As shown here, in the comparison 4, comparison was made with respect to four thermoelectric elements each having a substrate of W4.76 mm×L3.72 mm on which twenty pairs of thermoelectric elements having 0.32 mm square and 0.38 mm length are arranged.

As shown in FIG. 13, in comparative example 8, the thickness of the electrodes 12 and 22 and the thickness of the metalized layers 13 and 23 are equal to each other. On the other hand, in the embodiments 6-8, the thickness of the electrodes 12 and 22 is greater than the thickness of the metalized layers 13 and 23 in the order of the embodiments 8, 7 and 6.

As understood from the comparison of the resistance change rate in the embodiments 6-8 and the comparative example 8 shown in FIG. 13, the resistance change rates of the embodiments 6-8 fall within the acceptability criterion value of 1.0% or smaller with respect to any of average value, maximum value and minimum value, and from this, it can be judged that the damage degree of thermoelectric elements 31 and 32 is small. On the other hand, the resistance change rate of the comparative example 8 exceeds the acceptability criterion value of 1.0% with respect to average value and maximum value, and from this, it can be judged that the damage degree of thermoelectric elements 31 and 32 is large.

[Comparison 5]

FIG. 14 illustrates an arrangement in comparison 5. FIG. 15 illustrates conditions of each of the examples in the comparison 5. As shown here, in the comparison 6, comparison was made with respect to four thermoelectric elements each having a substrate of W2.8 mm×L2.6 mm on which ten pairs of thermoelectric elements having 0.32 mm square and 0.38 mm length are arranged.

As shown in FIG. 15, in comparative example 9, the thickness of the electrodes 12 and 22 and the thickness of the metalized layers 13 and 23 are equal to each other. On the other hand, in the embodiments 9-11, the thickness of the electrodes 12 and 22 is greater than the thickness of the metalized layers 13 and 23 in the order of the embodiments 11, 10 and 9.

As understood from the comparison of the resistance change rate in the embodiments 9-11 and the comparative example 9 shown in FIG. 15, the resistance change rates of the embodiments 9-11 fall within the acceptability criterion value of 1.0% or smaller with respect to any of average value, maximum value and minimum value, and from this, it can be judged that the damage degree of thermoelectric elements 31 and 32 is small. On the other hand, the resistance change rate of the comparative example 9 exceeds the acceptability criterion value of 1.0% with respect to average value and maximum value, and from this, it can be judged that the damage degree of thermoelectric elements 31 and 32 is large.

[Comparison 6]

FIG. 16 illustrates an arrangement in comparison 6. FIG. 17 illustrates conditions of each of the examples in the comparison 6. As shown here, in the comparison 6, comparison was made with respect to four thermoelectric elements each having a substrate of W3.2 mm×L2.5 mm on which twelve pairs of thermoelectric elements having 0.27 mm square and 0.38 mm length are arranged.

As shown in FIG. 17, in comparative example 10, the thickness of the electrodes 12 and 22 and the thickness of the metalized layers 13 and 23 are equal to each other. On the other hand, in the embodiments 12-14, the thickness of the electrodes 12 and 22 is greater than the thickness of the metalized layers 13 and 23 in the order of the embodiments 14, 13 and 12.

As understood from the comparison of the resistance change rate in the embodiments 12-14 and the comparative example 10 shown in FIG. 17, the resistance change rates of the embodiments 12-14 fall within the acceptability criterion value of 1.0% or smaller with respect to any of average value, maximum value and minimum value, and from this, it can be judged that the damage degree of thermoelectric elements 31 and 32 is small. On the other hand, the resistance change rate of the comparative example 10 exceeds the acceptability criterion value of 1.0% with respect to average value and maximum value, and from this, it can be judged that the damage degree of thermoelectric elements 31 and 32 is large.

According to the second exemplary embodiment, the displacement amount and force of the warp caused at the outer circumference of the substrates become smaller in accordance with the thickness of the electrode. With such an action, it becomes possible to prevent damages of thermoelectric elements caused by the warp of substrates.

Incidentally, the first and second exemplary embodiments may be combined. That is, it may be so configured that thermoelectric elements are arranged via electrodes in regions excluding a center region on opposing surfaces of the substrates, and further, each of the electrodes may be thicker than metalized layers.

### BRIEF DESCRIPTION OF THE DRAWINGS

FIG. 1 illustrates a basic configuration of a thermoelectric module according to a first exemplary embodiment.

FIG. 2 illustrates an action of the thermoelectric module according to the first exemplary embodiment.

FIG. 3A illustrates an arrangement of the embodiment 1 in comparison 1, and FIGS. 3B-3D illustrate arrangements of comparative examples 1-3 in the comparison 1.

FIG. 4 illustrates conditions of each of the examples in the comparison 1.

FIGS. 5A and 5B illustrate arrangements of the embodiments 2 and 3 in the comparison 2, and FIGS. 5C and 5D illustrate arrangements of comparative examples 4 and 5 in the comparison 2.

FIG. 6 illustrates conditions of each of the examples in the comparison 2.

FIGS. 7A and 7B illustrate arrangements of the embodiments 4 and 5 in the comparison 3, and FIGS. 7C and 7D illustrate arrangements of the comparative examples 6 and 7 in the comparison 3.

FIG. 8 illustrates conditions of each of the examples in the comparison 1.

FIG. 9 illustrates another configuration of the embodiment 1 shown in FIG. 2.

FIG. 10 illustrates another configuration of the embodiment 1 shown in FIG. 2.

FIG. 11 illustrates a basic configuration of a thermoelectric module according to a second exemplary embodiment.

FIG. 12 illustrates an arrangement in the comparison 4.

FIG. 13 illustrates conditions of each of the examples in the comparison 4.

FIG. 14 illustrates an arrangement in comparison 5.

FIG. 15 illustrates conditions of each of the examples in the comparison 5.

FIG. 16 illustrates an arrangement in comparison 6.

FIG. 17 illustrates conditions of each of the examples in the comparison 6.

FIG. 18 illustrates a basic configuration of a common thermoelectric module.

FIG. 19 illustrates an action of the common thermoelectric module.

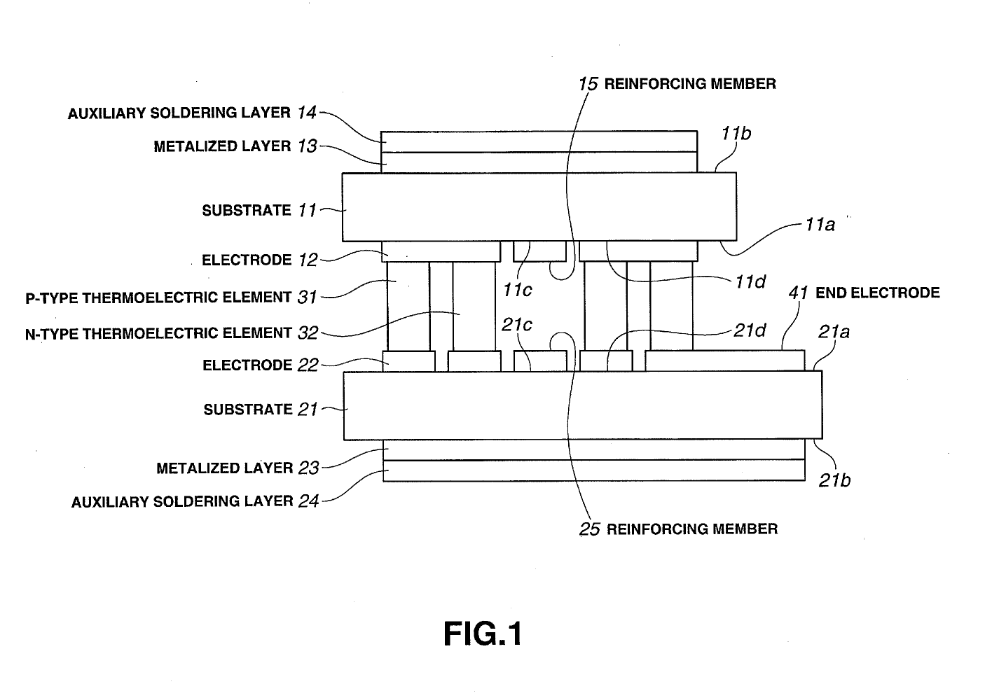

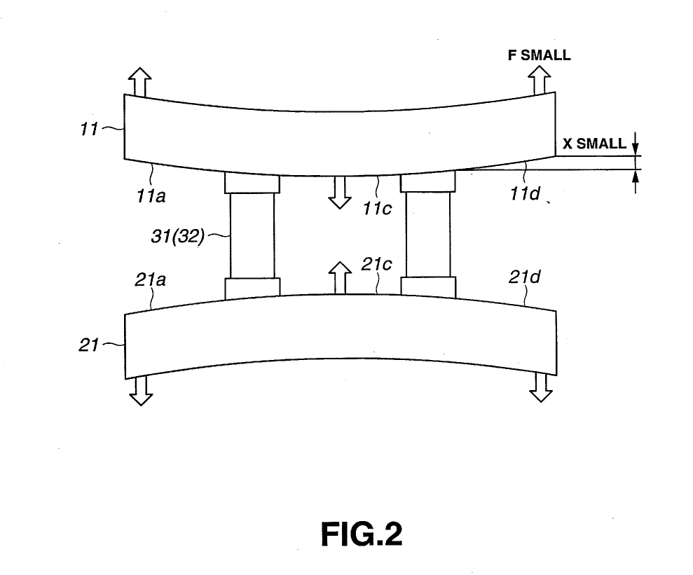

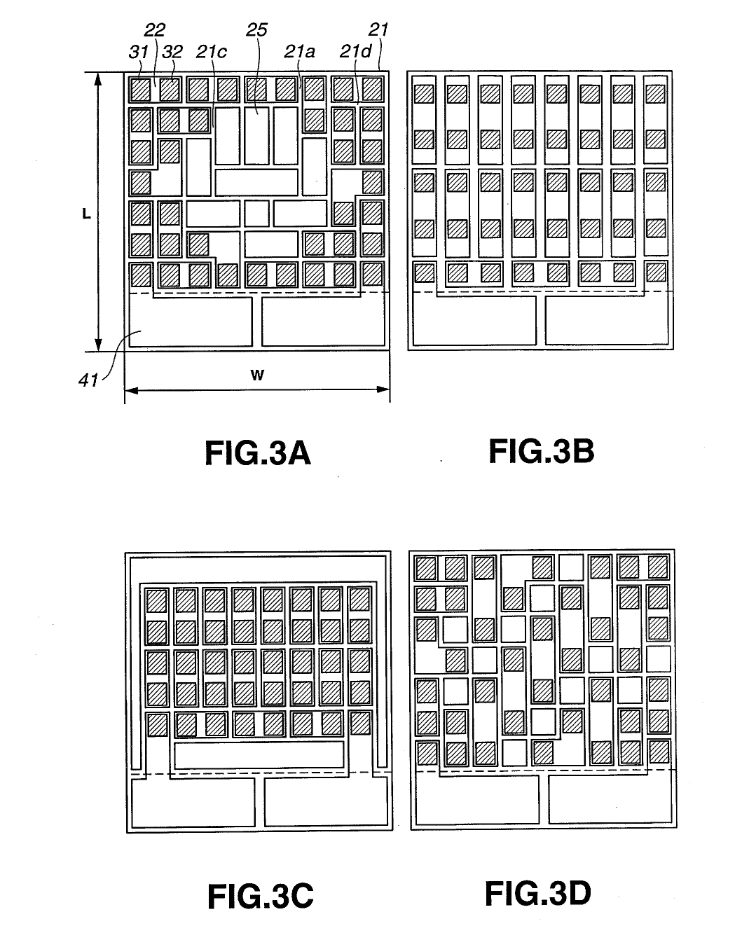

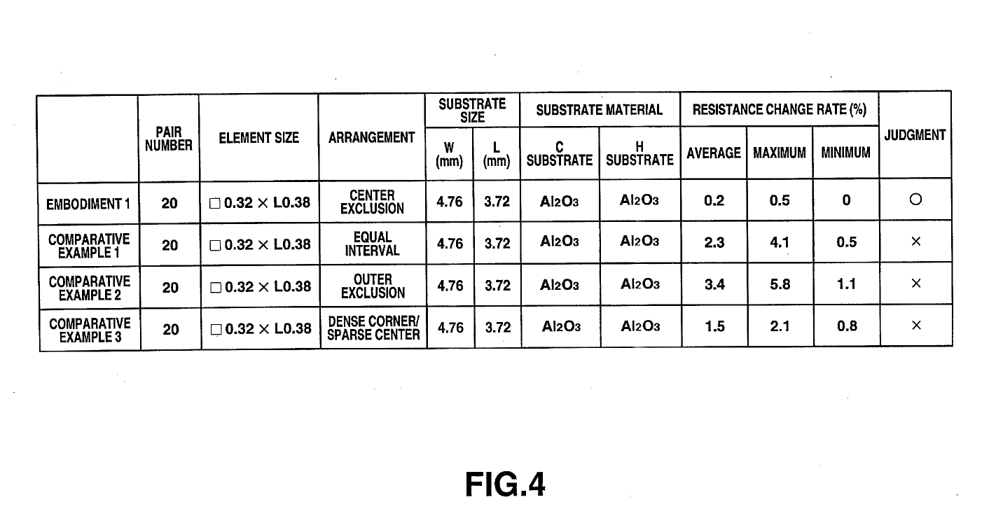

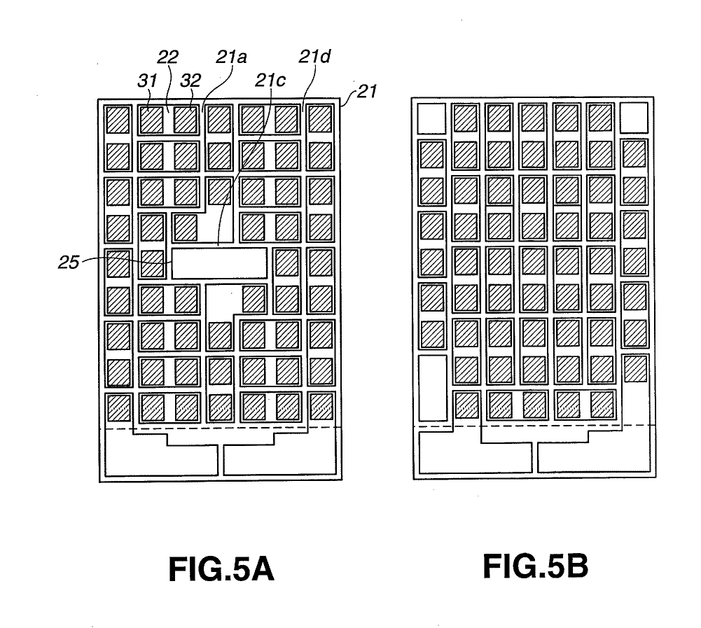

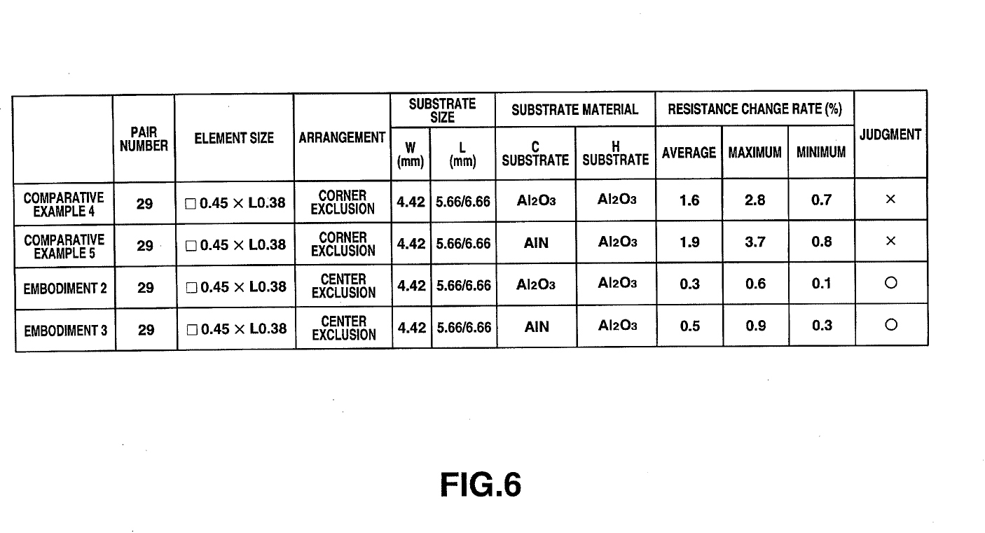

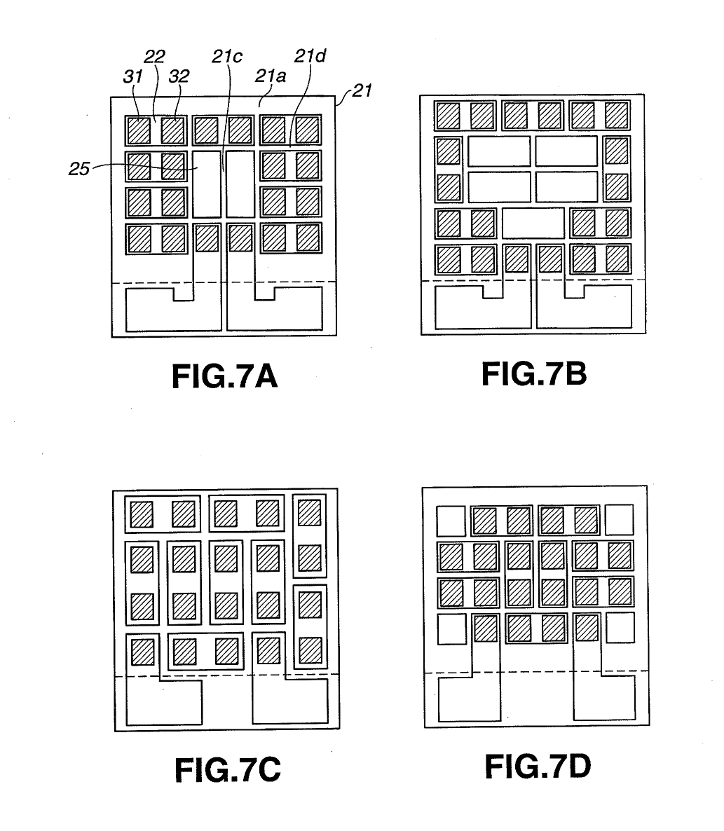

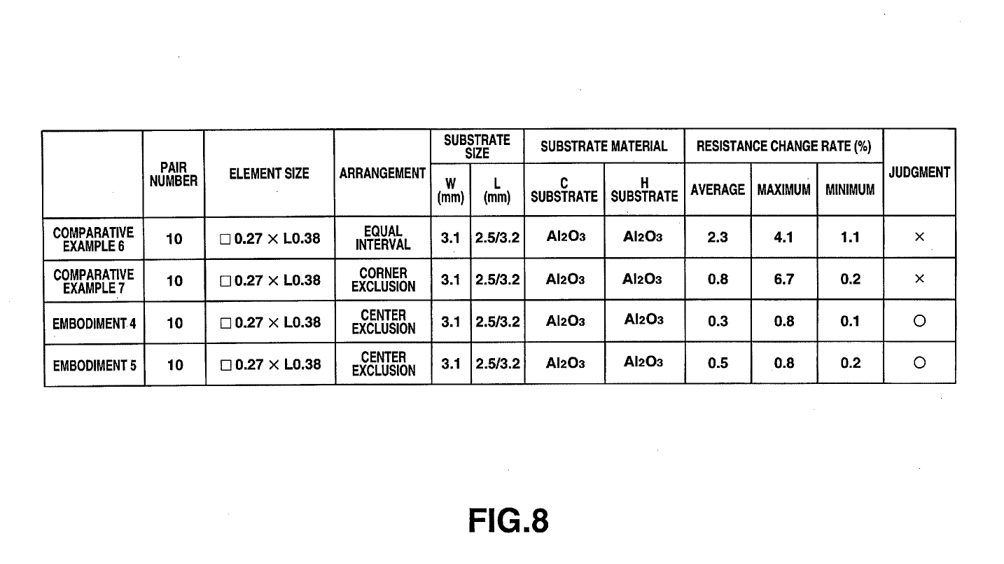

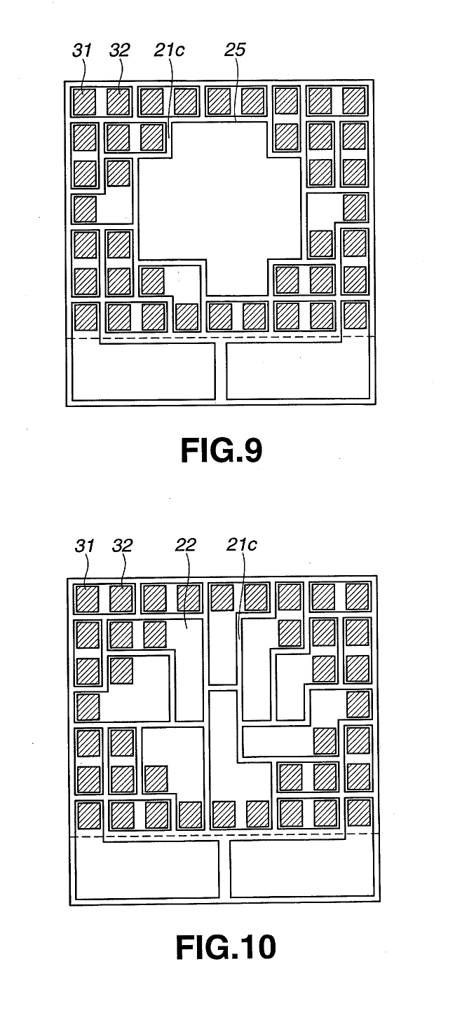

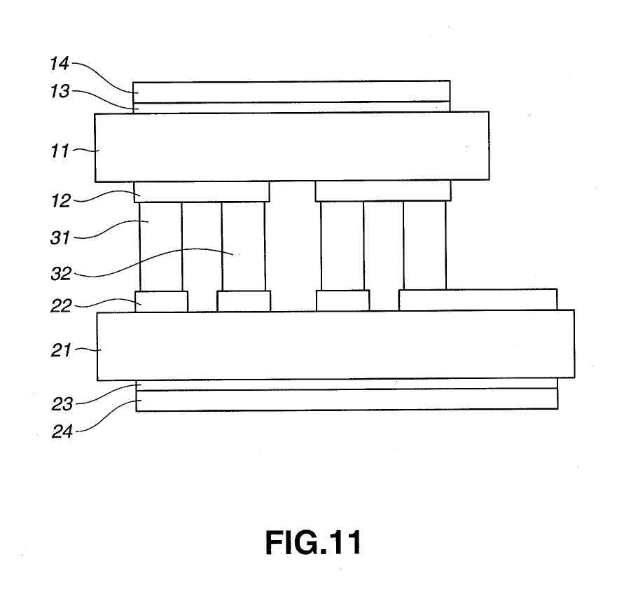

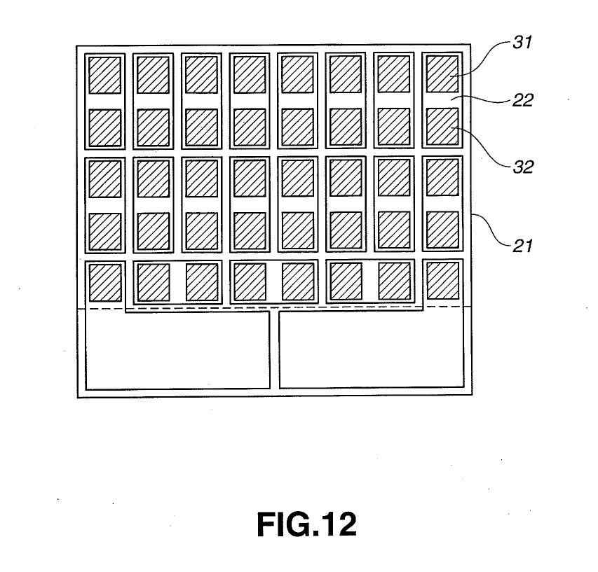

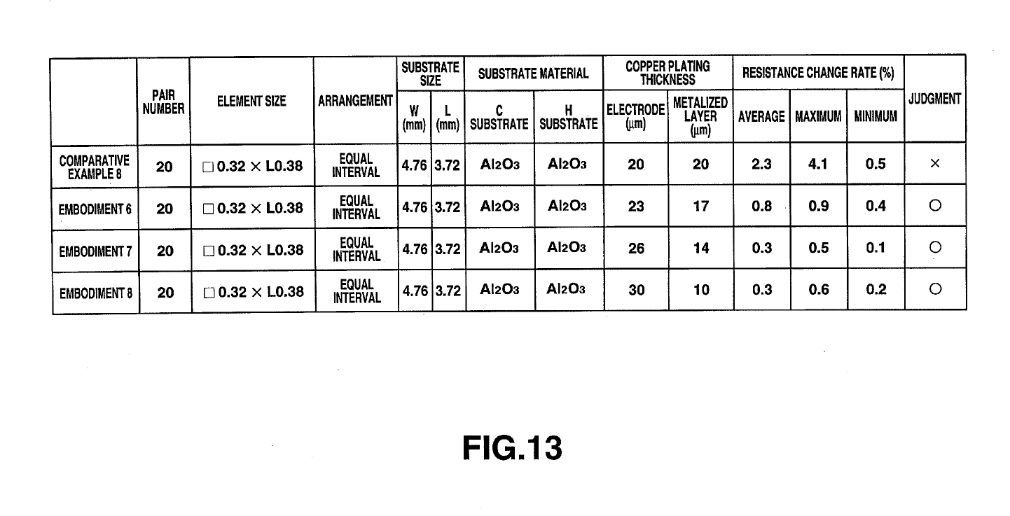

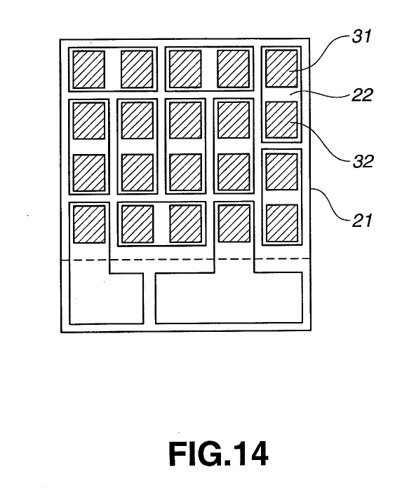

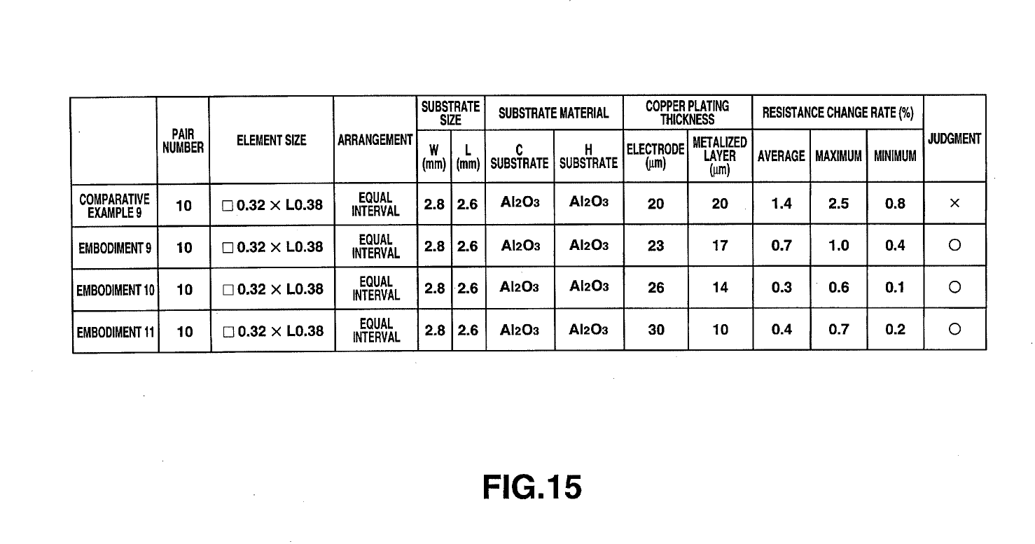

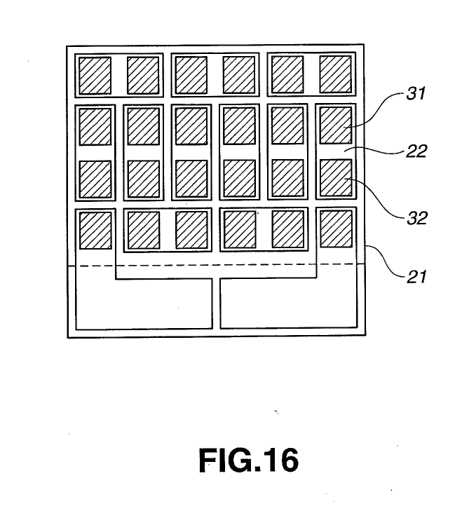

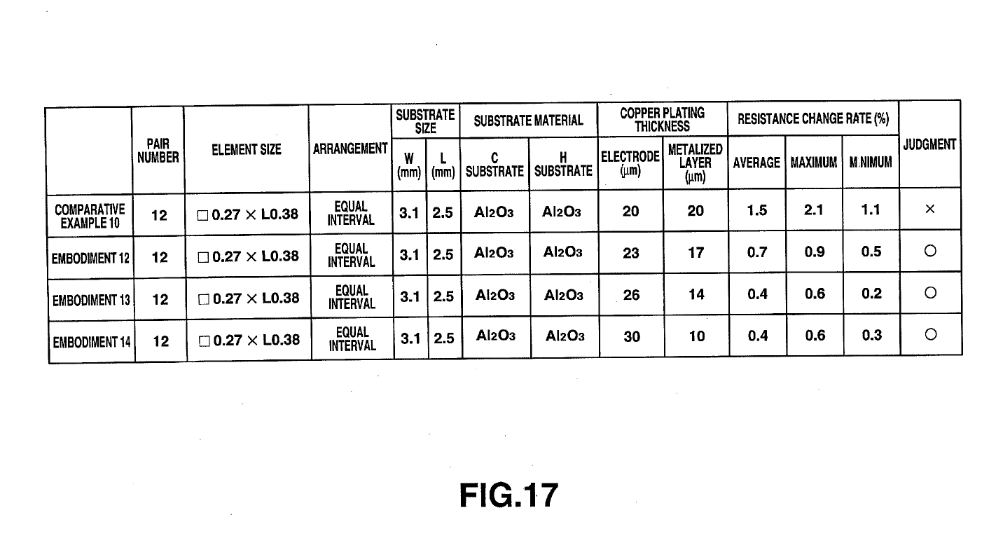

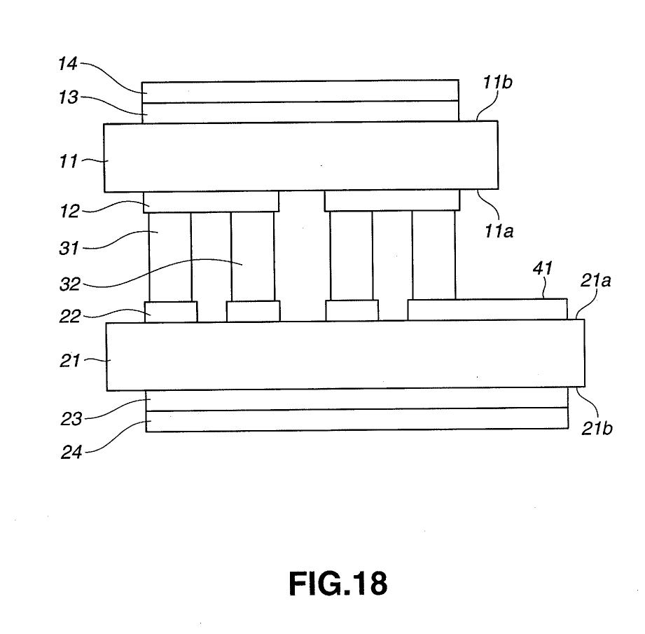

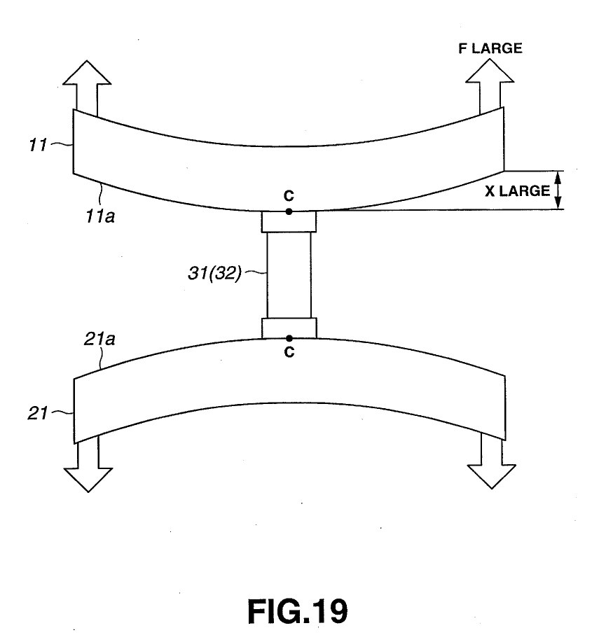

### EXPLANATION OF REFERENCE SYMBOLS

1, 2 thermoelectric module
11, 21 substrate
12, 22 electrode
13, 23 metalized layer
14, 24 pre-tinned solder layer
31 p-type thermoelectric element
32 n-type thermoelectric element

1. A thermoelectric module comprising: two mutually-opposing substrates; a plurality of electrodes formed on an opposing surface of each of the substrates; and a plurality of thermoelectric elements arranged on the opposing surface of each of the substrates in such a manner that one end thereof is joined to the opposing surface of one of the substrates via an electrode, and the other end thereof is joined to the opposing surface of the other one of the substrates via an electrode, in which the plurality of electrodes and the plurality of thermoelectric elements constitute a series circuit, and heat is transferred from the one of the substrates to the other substrate by passing an electric current through the series circuit, wherein
the plurality of thermoelectric elements are arranged with a high density in a region excluding a center region of the opposing surface of each of the substrates.

2. The thermoelectric module according to claim 1, wherein the center region has an area which is equal to or larger than four times of an area to which one of the thermoelectric elements is arranged, with respect to the opposing surface of each of the substrates.

3. The thermoelectric module according to claim 1, wherein a reinforcing member is formed in the center region.

4. The thermoelectric module according to claim 1, wherein an electrode to be connected to any of the plurality of thermoelectric elements extends into the center region.

5. The thermoelectric module according to claim 1, wherein the plurality of thermoelectric elements are arranged so that a change amount in a resistance value of the series circuit before and after formation of a pre-tinned solder layer on a reverse surface side of each of the substrates is 1.0% or smaller as compared with a resistance value of the series circuit before the formation of the pre-tinned solder layer.

6. A thermoelectric module comprising: two mutually-opposing substrates; a plurality of electrodes formed on an opposing surface of each of the substrates; a plurality of thermoelectric elements arranged on the opposing surface of each of the substrates in such a manner that one end thereof is joined to the opposing surface of one of the substrates via an electrode, and the other end thereof is joined to the opposing surface of the other one of the substrate via an electrode; and a pre-tinned solder layer formed on a reverse surface of each of the substrates, in which the plurality of electrodes and the plurality of thermoelectric elements constitute a series circuit, and heat is transferred from the one of the substrates to the other substrate by passing an electric current through the series circuit, wherein
a metalized layer is formed between the reverse surface of each of the substrates and the pre-tinned solder layer, and
the electrodes are thicker than the metalized layer to an extent that a change amount in a resistance value of the series circuit before and after the formation of the pre-tinned solder layer on the reverse surface side of each of the substrates is 1.0% or smaller as compared with a resistance value of the series circuit before the formation of the pre-tinned solder layer.
